(19) United States
(12) Patent Application Publication
(10) Pub. No.: US 2007/0091667 A1
(43) Pub. Date: Apr. 26, 2007

(54) Memory circuit as well as method for evaluating a memory datum of a CBRAM resistance memory cell

(75) Inventors: Thomas Rohr, Aschheim (DE); Corvin Liaw, Munchen (DE)

Correspondence Address: MORRISON & FOERSTER LLP, 1650 TYSONS BOULEVARD, SUITE 300, MCLEAN, VA, 22102, US

(73) Assignee: QIMONDA AG, Munchen (DE)

(21) Appl. No.: 11/582,347

(22) Filed: Oct. 18, 2006

Related U.S. Application Data
(63) Continuation of application No. PCT/EP05/12542, filed on Nov. 23, 2005.

(30) Foreign Application Priority Data
Dec. 2, 2004 (DE) 102004058132.0-55

(51) Int. Cl. G11C 11/00

(52) U.S. Cl. 365/148

(57) ABSTRACT

The invention relates to a memory circuit (Conductive Bridging RAM), and in particular to a CBRAM having CBRAM resistance elements as memory cells. The invention also relates to a method for evaluating a memory datum of a CBRAM resistance memory cell.

### TECHNICAL FEATURE OF THE INVENTION

The invention relates to a memory circuit (Conductive Bridging RAM), and in particular to a CBRAM having resistance elements as memory cells. The invention also relates to a method for evaluating a memory datum of a CBRAM resistance memory cell.

### BACKGROUND OF THE INVENTION

Novel types of memory circuits store an item of information in a resistance network, resistance elements being arranged in a matrix of word lines and bit lines. The resistance elements have a variable resistance, whereby an item of information can be stored as a memory datum.

CBRAM resistance elements (also called PMC resistance elements) are deemed promising; in these resistance elements it is possible to set the electrical resistance in a solid electrolyte by application of a programming current. Depending on the polarity and magnitude of the programming current, a relatively high or a relatively low resistance, which in each case defines a specific detectable state, can be set in the CBRAM resistance element.

The CBRAM resistance elements are arranged at the points of intersection between word lines and bit lines of the matrix made from the memory elements so that each CBRAM resistance element of a memory cell at such a point of intersection is connected to the corresponding word line by one connection and to the corresponding bit line by a further connection.

For the purpose of reading from the memory cells formed by the CBRAM resistance elements, an electrical quantity representing the resistance value of the memory cell is determined by applying a voltage or a current to the addressed memory cell with the aid of a read-out circuit and said quantity is compared with a further electrical quantity, which is determined in a manner dependent on a reference component, and the memory datum to be read out is determined in a manner dependent on the result of the comparison. This requires the reference component to be read by means of a reference read-out circuit, which is connected essentially in identical fashion to the read-out circuits connected to the bit lines, in order to obtain a comparison quantity. Since a separate reference component has to be provided essentially for each of the bit lines, the outlay on circuitry is thereby considerably increased.

The document US 2003/0031045 A1 e.g. discloses a read-out circuit for a resistive memory.

### SUMMARY OF THE INVENTION

The present invention provides a memory circuit of the type described above in which the outlay on circuitry can be reduced. The present invention also provides a method for reading out a memory datum from a CBRAM resistance memory cell in a matrix arrangement of CBRAM resistance memory cells, which method can be carried out with a reduced outlay on circuitry and with a lower energy consumption.

In one embodiment of the present invention, there is a memory circuit comprising memory cells having CBRAM resistance elements. The CBRAM resistance elements are arranged in a memory cell matrix on a bit line and on word lines, it being possible to set the resistance values of the CBRAM resistance elements by application of an electrical quantity in order to store a memory datum. The memory circuit furthermore comprises a reference resistance element, which is connected to the bit line and to a reference word line, the resistance value of the reference resistance element corresponding to a resistance threshold value. Voltage sources are provided, which are respectively connected to the word lines and the reference word line and are switchable in order to apply to the word line or the reference word line, respectively, an activation potential or a deactivation potential for activating or deactivating the word line or reference word line, respectively. A sense amplifier is provided on the bit line, said sense amplifier being suitable, given a bit line potential that is kept constant, for measuring a bit line current from the respective bit line. Furthermore, provision is made of a control unit, which, for the purpose of reading from one of the memory cells, applies the activation potential to the bit line and drives the voltage sources in such a way that, in a first cycle, the activation potential is applied to the reference word line and the deactivation potential is in each case applied to the word lines, and that, in a second cycle, the deactivation potential is applied to the reference word line, the activation potential is applied to the word line on which the memory cell to be read is situated, and the deactivation potential is applied to the rest of the word lines. The sense amplifier is connected to an evaluation unit, in which a quantity is determined which is dependent on the bit line current detected in the first cycle and the bit line current detected in the second cycle, in order to assign the electrical quantity determined to a memory datum.

The memory circuit according to the invention has the advantage that a separate sense amplifier that supplies an electrical comparison quantity to the evaluation unit does not have to be provided for the reference resistance elements to be provided. Instead, the reference resistance elements are connected to the bit line on which the CBRAM resistance elements to be read are also situated, so that the reference resistance element can be read by means of the same sense amplifier as the CBRAM resistance element to be read. It is thereby possible to save an additional sense amplifier.

The evaluation of the content of a memory cell formed by a CBRAM resistance element is carried out in two cycles, in which case, in a first cycle, firstly the deactivation potential is applied to the reference word line and the deactivation potential is applied to the word lines. This has the effect that a current flows via the reference resistance element and the bit line to the sense amplifier, which current is measured with the aid of the sense amplifier and made available to the downstream evaluation unit in the form of an electrical quantity. In a second cycle, which is assumed after the first state, the deactivation potential is applied to the reference word line and also to the non-selected word lines and the activation potential is applied to the word line on which the memory cell to be read is situated. Once again the bit line current is measured by the sense amplifier and a corresponding quantity dependent thereon is made available in the evaluation unit.

The corresponding memory datum is assigned in a manner dependent on the electrical quantities measured in the two cycles, in particular on the difference between the electrical quantities.

A further advantage is that, by virtue of using the same sense amplifier for reading from the reference resistance element and the CBRAM resistance element, the influence of a voltage offset generated in the sense amplifier on the bit line is eliminated since the offset when reading from the reference resistance element and the CBRAM resistance element has the same magnitude and the influence of the offset in the two cycles cancels one another out upon difference formation.

In accordance with one preferred embodiment, the evaluation unit has a memory element, which stores a quantity representing the bit line current measured during the first cycle, the evaluation unit having a differential unit in order to form the electrical quantity depending on the difference between the bit line current received during the first cycle and a bit line current received during the second cycle. In particular, the memory element has a capacitor in order to store an electrical quantity dependent on the bit line current detected during the first cycle.

It may be provided that the sense amplifier has an operational amplifier with an input connected to the bit line, a negative feedback circuit being provided in order to keep the bit line potential on the bit line constant during the detection of the bit line current.

The voltage sources and the sense amplifier are preferably coordinated with one another in such a way that the deactivation potential of the voltage sources corresponds to the bit line potential at which the corresponding bit line is held by the corresponding sense amplifier. It is ensured in this way that the deactivated word lines and a deactivated reference word line, respectively, are ideally de-energized since their voltage is dropped between the deactivation potential and the bit line potential.

In accordance with another embodiment, the reference resistance elements may have a plurality of interconnected CBRAM resistance elements which are in each case set to a resistance value corresponding to a first state of the memory datum, or to another resistance value corresponding to a second state of the memory datum. In this way, the reference resistance elements may likewise be formed with the aid of CBRAM resistance elements which are programmed to a fixed value.

The control unit may assume the first cycle, in which the corresponding potentials are applied, during a first time duration and may assume the second state during a second time duration. In this way, during the first time duration, it is possible for a capacitance to be charged or discharged depending on the bit line current in order, in the first cycle, to attain a defined charging potential depending on the bit line current and thus to store a quantity dependent on the bit line current in the first cycle. This quantity is used as a reference quantity for the evaluation of the bit line current flowing in the second cycle.

In still another embodiment of the present invention, there is a method for evaluating a memory datum of a CBRAM resistance memory cell. The CBRAM resistance memory cell is arranged in a group of CBRAM resistance memory cells on a bit line and on word lines, it being possible to set the resistance values of the CBRAM resistance memory cells by application of an electrical quantity in order to store a respective memory datum. A reference resistance element is connected to the bit line and to a reference word line, the resistance value of the reference resistance element corresponding to a resistance threshold value. The method has the steps of: applying a deactivation potential to the word lines and applying an activation potential to the reference word line; detecting a resulting bit line current in a first cycle; applying a deactivation potential to the reference word line and applying the activation potential to the word line on which the memory cell to be read is situated; detecting a bit line current that results in the second mode; and generating an electrical quantity dependent on the bit line current detected in the first cycle and the bit line current detected in the second cycle, and assigning a memory datum.

In yet another embodiment according to the invention, a method has the advantage that the CBRAM resistance memory cell and the reference resistance element can be connected to a single bit line, a resistance value of the CBRAM resistance memory cell and a resistance value of the reference resistance element being read out successively by detecting a corresponding bit line current and determining the memory datum in a manner dependent on the bit line currents that result when reading from the reference resistance element and when reading from the CBRAM resistance memory cell.

It may furthermore be provided that a quantity representing the bit line current that results in the first cycle is stored in order, in or after the second cycle, to determine the memory datum in a manner dependent on the bit line current detected in the first cycle.

In accordance with still another embodiment, the step of applying the deactivation potential to the word lines and applying an activation potential to the reference word line in the first cycle may be carried out during a first time duration in order to form storage of a charge dependent on the bit line current in a capacitance. It may furthermore be provided that the step of applying a deactivation potential to the reference word line and applying the activation potential to the word line on which the memory cell to be read is situated is carried out during a second time duration. Preferably, during the first cycle a charge store is charged or discharged with a quantity dependent on the bit line current and during the second cycle the charge store is discharged or charged with a quantity dependent on the bit line current.

### BRIEF DESCRIPTION OF THE DRAWINGS

Preferred embodiments of the present invention are explained in more detail below with reference to the accompanying drawings, in which:

FIG. 1 shows a detail from a memory cell matrix with reference resistance elements and memory cells with CBRAM resistance elements in accordance with one embodiment of the invention.

FIG. 2 shows a more detailed illustration of the sense amplifier and of the evaluation unit for reading the reference resistance value in a first cycle.

FIG. 3 shows a more detailed illustration of the sense amplifier and of the evaluation unit of FIG. 2 in a second cycle when receiving the bit line current depending on the resistance value of the CBRAM resistance element.

FIG. 4 shows an illustration of a sense amplifier and of an evaluation unit in accordance with a further embodiment.

FIGS. 5a to 5c show possible configurations of the reference resistance element which is constructed with the aid of CBRAM resistance elements.

### DETAILED DESCRIPTION OF THE INVENTION

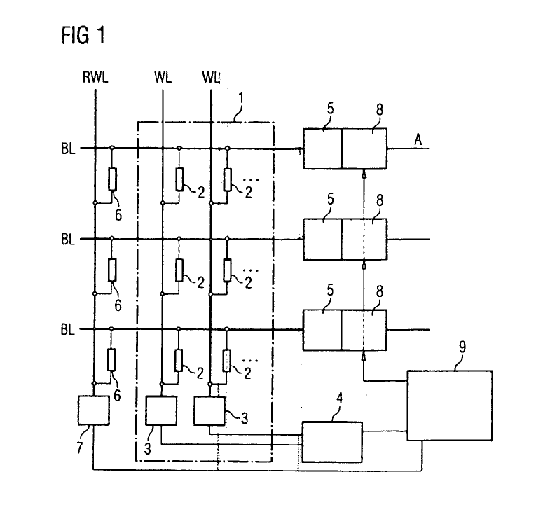

FIG. 1 illustrates a memory circuit according to the invention, which has a memory cell matrix 1 comprising word lines WL and bit lines BL which cross one another and at the crossover points of which a memory cell is arranged in each case. The memory cell is arranged in each case. The memory cells have CBRAM resistance elements 2, which are in each case connected to the respective word line WL by a first connection and to the respective bit line BL by a second connection. Selection switches and the like are not provided in this embodiment.

The word lines WL are driven by means of voltage sources 3 connected to an address decoder 4, which drives the voltage sources 3, so that the latter apply an activation potential V_{act} or a deactivation potential V_{deact} to the respective word line WL. The bit lines BL are in each case connected to a sense amplifier 5, which detects a bit line current while the respective sense amplifier 5 holds the bit line BL at a predefined bit line potential V_{BL}. The sense amplifiers 5 are essentially always active and apply the bit line potential V_{BL} to the bit lines BL, a deactivation potential V_{deact} corresponding to the bit line potential VBL being applied to the word lines WL for the purpose of deactivating the CBRAM resistance memory cells 2 by the corresponding voltage sources 3.

A word line WL is selected by the address decoder 4 driving the respective voltage source 3 in such a way that the latter applies an activation potential to the word line WL, thereby effecting a voltage drop between the activated word line WL and the bit lines BL, which are in each case held at the bit line potential, across the CBRAM resistance element 2, as a result of which a current flows from the word line WL onto the bit line BL and can be detected by the sense amplifier 5.

Each bit line BL is furthermore connected to a reference resistance element 6, which are arranged along a reference word line. The reference word line RWL essentially crosses the bit lines BL and the reference resistance element 6 is connected, at the crossover points, to the reference word line by a first connection and to the respective bit line BL by a second connection. The reference word line is supplied with a voltage by means of a reference voltage source 7 in order to activate and deactivate the reference word line RWL, preferably with the same activation potential V_{act} and deactivation potential V_{deact}, respectively, as the word lines WL are supplied by the voltage sources 3.

The CBRAM resistance elements 2 can be programmed by a write current with the aid of a write circuit (not shown) and thereby acquire a relatively high or a relatively low resistance value depending on the memory datum to be stored. The reference resistance elements 6 are predefined with a resistance value or set to a resistance value which lies between the relatively high and the relatively low resistance value which the CBRAM resistance elements 2 can assume.

The sense amplifiers 5 are in each case coupled to an evaluation circuit 8, in which an evaluation of the read-out bit line current of the corresponding bit line BL is performed. The evaluation of the bit line current is carried out with the aid of a measurement operation controlled with the aid of a control unit 9. The control unit 9 is connected to the evaluation units 8, to the address decoder 4 and to the reference voltage source 7 in order to control the read-out of a memory datum.

A memory datum is read out in two cycles. In a first cycle, the control unit 9 drives the reference voltage source 7 in such a way that the reference voltage source 7 applies the activation potential V_{act} to the reference word line RWL and thus effects a voltage drop between the reference resistance elements 6 and the respective bit line BL. In the evaluation unit 8 selected by the control unit 9, the bit line current received by the associated sense amplifier 5 is converted into a suitable electrical quantity, and the latter is buffer-stored, so that it is available after a second cycle following the first cycle. By way of example, the electrical quantity may be stored as a potential in a capacitance.

In the second cycle, the control unit 9 drives the reference voltage source 7 in such a way that a deactivation potential V_{deact} is applied to the reference word line RWL, and, essentially simultaneously or with a small temporal separation, drives the address decoder 4 in such a way that, in accordance with the memory cell to be addressed, one of the voltage sources 3 is activated, so that the latter applies the activation potential V_{act} to the addressed word line WL. The rest of the voltage sources 3 on the rest of the word lines WL supply a deactivation potential V_{deact} essentially corresponding to the bit line potential BL, so that essentially no appreciable current flows via the non-addressed CBRAM resistance elements 2. The control unit 9 drives the selected evaluation unit 8 in such a way that an output signal is output on the respective output line A in a manner dependent on the bit line current detected during the first cycle and in a manner dependent on the bit line current detected in the second cycle and it corresponds to the memory datum to be read out.

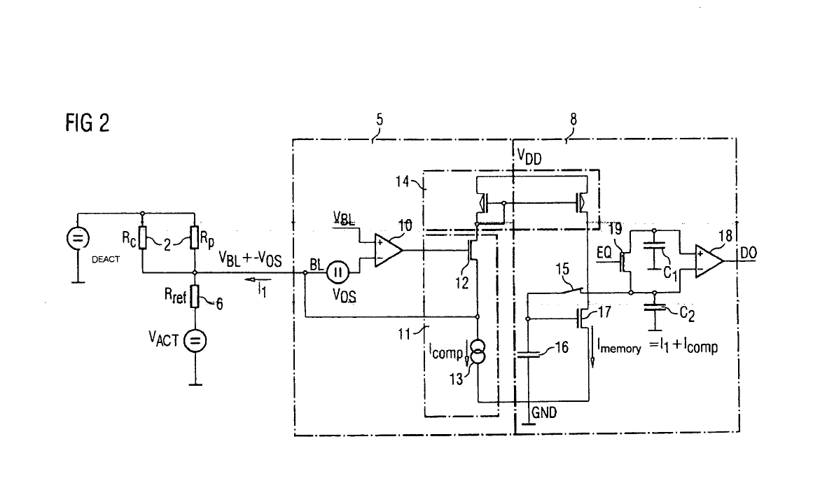

FIG. 2 illustrates a more detailed circuit diagram of a sense amplifier 5 and of an evaluation unit 8 on a bit line BL, the reference resistance element 6 on the corresponding bit line BL and the selected and non-selected CBRAM resistance elements 2 being represented as resistor symbols in a corresponding interconnection. The resistance value of the selected CBRAM resistance element 2 is specified by Rc, the resistance value of the non-selected CBRAM resistance elements 2 which are situated on the selected bit line and are connected in parallel with one another are specified by Rp, and the resistance value of the reference resistance element 6 is specified by R_{ref}. In the first cycle, the first connection of the reference resistance element 6 is connected to the activation potential V_{act}, and it is connected to the bit line BL by the second connection. Both the addressed CBRAM resistance element 2 Rc and the rest of the CBRAM resistance elements 2 Rp connected to the bit line BL are connected to the bit lines by their second connection and to a deactivation potential V_{deact} by their first connections.

The sense amplifier 5 essentially has an operational amplifier 10, to the output of which a negative feedback circuit 11 is connected, which is coupled to an inverting input of the operational amplifier 10. The bit line potential V_{BL}, which essentially corresponds to the deactivation potential V_{deact}, is applied to the non-inverting input of the operational amplifier 10. On account of fluctuations of the component parameters, in particular of the operational amplifier and of the negative feedback circuit 11, the voltage established on the bit line BL does not exactly correspond to the bit line potential V_{BL}, but rather has imposed on it an offset which is not known and which usually has the effect that a quiescent current dependent on the offset potential Vos flows between the voltage sources 3, which apply the deactivation potential V_{deact} to the word lines WL and the bit line BL.

The negative feedback circuit 11 has for example an n-channel field effect transistor 12, the control connection of which is coupled to the output of the operational amplifier 10. A source connection of the n-channel field effect transistor 12 is connected to a first connection of a current source 13, the second connection of which is connected to an earth potential GND. A drain connection of the field effect transistor 12 is connected to a high supply voltage potential V_{DD} via a current mirror circuit 14. The source connection of the field effect transistor 12 and the first connection of the current source 13 are connected to the bit line BL. The current I1 flowing onto the bit line via the reference resistance element 6 on account of the activation potential V_{act} is thus impressed into the field effect transistor 12 and mirrored into a further current path via the current mirror circuit 14. The current source 13 may alternatively be omitted if the activation potential V_{act} is less than the bit line potential V_{BL}, so that a positive current always flows between the drain connection and the source connection of the n-channel field effect transistor 12. Situated in the further current path is a switch 15, which is controlled by the control unit 9 and is formed as a transistor, for example. The switch 15 is closed in the first cycle. By means of the switch 15, a capacitor 16 is switched in the current path, which capacitor is charged or discharged by the current mirrored into the further current path, as a result of which the voltage across the capacitor 16 rises or falls. The first connection of the capacitor 16 is furthermore connected to a control connection of a further field effect transistor 17 which, as the capacitor voltage rises, becomes conductive to an extent determined by the capacitor voltage. A current value which flows through the further current path is established in the further field effect transistor 17.

If the control unit 9 switches into the second cycle, then the switch 15 is opened, so that the setting which then exists, that is to say the current which flows through the further field effect transistor 17, is maintained. In the circuit illustrated, the further field effect transistor 17 operates as a current source which is set by the charge potential of the capacitor 16.

In the first cycle, a quantity essentially corresponding to the current value I_{memory}=I₁+I_{comp} is stored, I_{comp} corresponding to the current value supplied by the current source 14. The storage of the corresponding quantity takes place by charge storage on the capacitance 16, which is preferably formed as a gate capacitance of the further field effect transistor (memory transistor 17). The gate voltage is retained even after the opening of the switch 15 and has the effect that I_{memory} also flows in the second cycle.

The output of the current mirror 14, which provides the current on the further current path, is connected to a first input of a comparator 18. The first input of the comparator 18 is connected to a second input of the comparator 18 via an equalizing transistor 19. The equalizing transistor 19 has a control input, which is driven with an equalize signal EQ. The first and second inputs of the comparator 18 have capacitances designated as evaluator capacitances C1 and C2.

In the first cycle, the signal EQ is at “high” and has the effect that the equalizing transistor 19 connects the evaluator capacitances C1 and C2 to the drain connection of the memory transistor 17. In the second cycle, EQ is set to “low” and the evaluator capacitances C1 and C2 are thus isolated from one another. After the isolation of the evaluator capacitances C1 and C2, the potential present previously is stored as a charge potential on the first evaluator capacitance Cl which serves as a reference potential for the evaluation of the signal present at the first input of the comparator 18.

In the second cycle, the first connections of the reference resistance element 6 and of the non-addressed CBRAM resistance elements 2 are connected to the deactivation potential V_{deact} and the first connection of the addressed CBRAM resistance element 2 is connected to the activation potential V_{act}. The bit line current I₂ then flows from the activation potential V_{act} via the addressed CBRAM resistance element 2 onto the bit line BL and thus brings about a further bit line current I₂ in a manner dependent on the bit line potential V_{BL} and the offset potential of the operational amplifier 10, said offset potential being brought about by the component parameters.

In the second cycle, the switch 15 is open (controlled by the control unit 9), so that the charge potential stored in the capacitor 16 is essentially constant, thus resulting in a specific constant current value I_{memory} through the further field effect transistor 17. If the bit line current I2 read out in the second cycle is then mirrored in the further current path, a resulting voltage is produced at the drain connection of the further field effect transistor 17 and is interpreted by a downstream comparator 18 and provides a corresponding output signal A.

The circuit formed by the capacitor 16, the switch 15 and the further field effect transistor 17 is essentially a subtractor by means of which a first current value stored by means of the closed switch 15 is subtracted from a current value applied with switch 15 open and a voltage value corresponding to the subtraction result is output at the drain connection of the further field effect transistor 17.

The two-stage read-out process of a memory cell having a CBRAM resistance element has the further advantage that the bit line current I₁ read out in the first cycle and the bit line current I₂ read out in the second cycle are influenced by the same offset potentials Vₒₛ, which are eliminated in the evaluation unit 8 by subtraction of the two current values. This follows from:

$${I}_{1} = \frac{{V}_{os}}{{R}_{c}} \pm \frac{{V}_{os}}{{R}_{p}} + \frac{{V}_{act} \pm {V}_{os} + {V}_{deact}}{{R}_{ref}}$$

$${I}_{2} = \frac{{V}_{os}}{{R}_{p}} \pm \frac{{V}_{os}}{{R}_{ref}} + \frac{{V}_{act} \pm {V}_{os} - {V}_{deact}}{{R}_{c}}$$

$${I}_{C C 3} = {I}_{2} - {I}_{1} = \frac{{V}_{act} - {V}_{deact}}{{R}_{c}} - \frac{{V}_{act} - {V}_{deact}}{{R}_{ref}}$$

It is evident that the influence of the offset potential Vₒₛ can be completely eliminated (±Vₒₛ specifies that the offset potential can assume different signs). In this way, the memory circuit according to the invention first of all has the advantage that circuit area can be saved, since, instead of a separate sense amplifier for the reference resistance element 6, only a single sense amplifier is used both for the reference resistance element 6 and for the CBRAM resistance elements 2 by virtue of both the reference resistance element 6 and the CBRAM resistance elements 2 being situated on the same bit line. Moreover, the method eliminates the parasitic currents—arising as a result of the offset voltage—through the parallel resistances Rₚ.

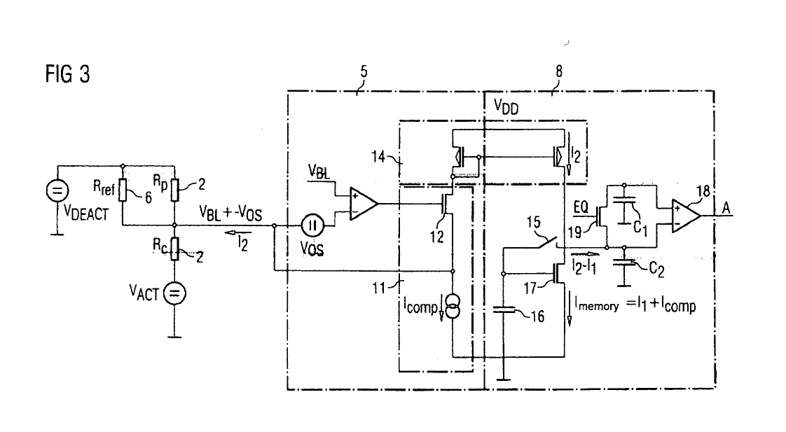

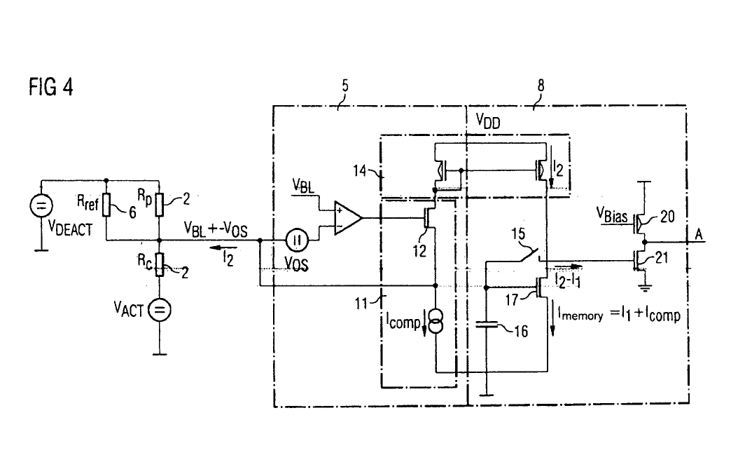

FIG. 4 illustrates a further embodiment of a sense amplifier and of an evaluation unit. In contrast to the embodiment in FIGS. 2 and 3, the evaluation unit 8 differs in the fact that, instead of the comparator 18 and the equalizing transistor 19, an output inverter circuit is provided in order to drive the signal (potential) present at the drain connection of the further field effect transistor 17 onto the output as output signal A. In this exemplary embodiment, the output inverter circuit is formed with the aid of a p-channel transistor 20 and an n-channel transistor 21, which are connected in series with one another. A control connection of the p-channel transistor 20 is connected to a defined bias voltage V_{bias} in order to set the pull-up current path of the inverter. A control connection of the n-channel field effect transistor 21 of the output inverter circuit is connected to the drain connection of the further field effect transistor 17, so that an output signal present at the drain connection of the further field effect transistor 17 is amplified in inverted fashion by the inverter circuit. The use of such an output inverter circuit is sufficient in the case of the present circuit since, on account of the large resistance ratio between the resistance values assigned to the different states of the CBRAM resistance elements, a relatively small amplification of the signal at the drain connection of the further field effect transistor 17 suffices to provide the output signal A.

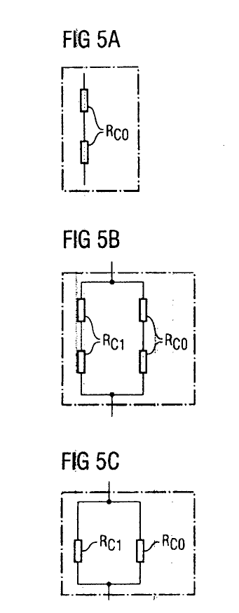

FIGS. 5a to 5c illustrate possible configurations of the reference resistance element 6. In the embodiment of FIG. 5a, the reference resistance element 6 is formed by two CBRAM resistance elements which are set to a resistance value R_{c0} corresponding to the relatively low resistance value of the CBRAM resistance elements. The CBRAM resistance elements are connected in series so that a resistance is formed which corresponds to double the relatively low resistance value and thus lies between the low resistance value and the relatively high resistance value.

FIG. 5b illustrates a further possibility for a construction of a reference resistance element. It has four CBRAM resistance elements, in which case two series-connected CBRAM resistance elements having the relatively high resistance value R_{c1} and two series-connected CBRAM resistance elements having the relatively low resistance value R_{c0} are connected in parallel with one another.

In a further embodiment, it is possible to form the reference resistance element 6 with two CBRAM resistance elements connected in parallel with one another, one of the CBRAM resistance elements being provided with a relatively high resistance value R_{c1} and the other CBRAM resistance element being provided with a relatively low resistance value R_{c0}. Since the resulting resistance value is smaller than the relatively low resistance value of a CBRAM resistance element, a potential which is different from the activation potential of the voltage sources 3 can be used as an activation potential V_{act} generated by the reference voltage source 7.

What is claimed is:

1. A memory circuit, comprising:
memory cells having CBRAM resistance elements, which are arranged in a memory cell matrix on a bit line and on word lines, the resistance values of the CBRAM resistance elements configured to be set by application of an electrical quantity to store a memory datum;
a reference resistance element, which is connected to the bit line and to a reference word line, the resistance value of the reference resistance element corresponding to a resistance threshold value;
voltage sources, which are respectively connected to the word lines and the reference word line, and are switchable to apply to the word line or the reference word line, respectively, an activation potential or a deactivation potential for activating or deactivating the corresponding word line or reference word line, respectively;
a sense amplifier on the bit line, the sense amplifier being suitable, given a bit line potential that is kept constant, for measuring a bit line current from the bit line;
a control unit, which reads from one of the memory cells, applies the bit line potential to the bit line and drives the voltage sources such that, in a first cycle, the activation potential is applied to the reference word line and the deactivation potential is in each case applied to the word lines, and in a second cycle, the deactivation potential is applied to the reference word line, the activation potential is applied to the word line on which the memory cell to be read is situated, and the deactivation potential is applied to the rest of the word lines; and
an evaluation unit, which is connected to the sense amplifier to determine an electrical quantity dependent on the bit line current detected in the first cycle and the bit line current detected in the second cycle, and to assign the electrical quantity determined to a memory datum.

2. The memory circuit according to claim 1, wherein the evaluation unit comprises a memory element, which stores a quantity representing the bit line current measured during the first cycle, and the evaluation unit has a differential unit to form the quantity depending on the difference between the bit line current received during the first cycle and a bit line current received during the second cycle.

3. The memory circuit according to claim 1, wherein the sense amplifier has an operational amplifier having an input connected to the bit line, a negative feedback circuit being provided to keep the bit line potential on the bit line constant during the detection of the bit line current.

4. The memory circuit according to claim 3, the voltage sources and the sense amplifier being coordinated with one another such that the deactivation potential of the voltage sources corresponds to the bit line potential at which the corresponding bit line is acquired by the sense amplifier.

5. The memory circuit according to claim 1, wherein the reference resistance elements having a plurality of CBRAM resistance elements which are in each case set to a resistance value corresponding to a first state of the memory datum or to a resistance value corresponding to a second state of the memory datum.

6. The memory circuit according to claim 1, wherein the control unit assumes the first cycle during a first time duration.

7. The memory circuit according to claim 6, wherein the control unit assumes the second cycle during a second time duration.

8. The memory circuit according to claim 6, wherein the evaluation unit has a capacitance, which, during the first time duration, stores a charge dependent on the bit line current which flows in the first cycle from the bit line, and having a current source, which, in the second cycle, depending on the charge, generates a current on which the electrical quantity is dependent.

9. A method for evaluating a memory datum of a CBRAM resistance memory cell situated in a group of CBRAM resistance memory cells on a bit line and a word line, the resistance values of the CBRAM resistance memory cells configured to be set by application of an electrical quantity to store a respective memory datum, a reference resistance element being connected to the bit line and to a reference word line, and the resistance value of the reference resistance element corresponding to a resistance threshold value, comprising:
a) applying a deactivation potential to the word lines and applying an activation potential to the reference word line in a first cycle;
b) detecting a bit line current that results in the first cycle;
c) applying a deactivation potential to the reference word line and applying the activation potential to the word line on which the memory cell to be read is situated, in a second cycle,
d) detecting a bit line current that results in the second cycle;
e) generating an electrical quantity dependent on the bit line current detected in the first cycle and the bit line current detected in the second cycle, and assigning a memory datum.

10. The method according to claim 9, a quantity represented by the bit line current detected in step b) being stored.

11. The method according to claim 10, step a) of applying the deactivation potential and the activation potential being carried out during a first time duration.

12. The method according to claim 11, step c) of applying the deactivation potential and the activation potential being carried out for a second time duration.

13. The method according to claim 12, during the first cycle a charge store being charged with a charge dependent on the bit line current, and during the second cycle, depending on the charge in the charge store, a current being generated on which the generated electrical quantity is dependent.
